(19) United States
(12) Patent Application Publication
(10) Pub. No.: US 2025/0349809 A1
(43) Pub. Date: Nov. 13, 2025

(54) SEMICONDUCTOR PACKAGE AND METHOD FOR MANUFACTURING THE SAME

(71) Applicant: Samsung Electronics Co., Ltd., Suwon-si (KR)

(72) Inventors: KYUNG DON MUN, Suwon-si (KR); HYEONJEONG HWANG, Suwon-si (KR)

(21) Appl. No.: 18/978,665

(22) Filed: Dec. 12, 2024

(30) Foreign Application Priority Data
May 10, 2024 (KR) 10-2024-0061995

(51) Int. Cl. H01L 25/16; H01L 23/00; H01L 23/48; H01L 23/498; H01L 25/00; H10B 80/00

(52) U.S. Cl. CPC H01L 25/162; H01L 23/481; H01L 23/49816; H01L 24/24; H01L 25/50; H01L 2224/24146; H10B 80/00

(57) ABSTRACT

A semiconductor package including a first redistribution layer structure, a logic die on the first redistribution layer structure, a plurality of conductive posts on the first redistribution layer structure and next to the logic die, a second redistribution layer structure on the logic die, and a processing in memory (PIM) die on the second redistribution layer structure.

### CROSS-REFERENCE TO RELATED APPLICATION

This application claims the benefit of priority under 35 U.S.C. § 119 to Korean Patent Application No. 10-2024-0061995 filed in the Korean Intellectual Property Office on May 10, 2024, the entire contents of which are incorporated herein by reference.

### BACKGROUND

The present disclosure relates to a semiconductor package and a method for manufacturing the same.

The conventional von Neumann structure works in a way that memory stores data, and logic retrieves data from memory and performs operations. In such a structure where the functions of memory and logic are separated, if operation tasks are concentrated in the logic, it takes a lot of time to move data between the memory and logic, causing a bottleneck. In particular, in fields where large-scale parallel operations are performed or high-performance computing is required, it is essential to transfer data at high-speed between memory and logic.

To solve these problems, processing in memory (PIM) semiconductors are being researched. PIM semiconductors is a semiconductor architecture in which processor functions (and the hardware for performing the processor functions) required for operation tasks are added to memory. PIM semiconductors may solve the problem of data movement stagnation between memory and logic, and have the advantage of enabling fast operation speeds and low power consumption.

Meanwhile, in mobile devices, in order to ensure the shortest path between a memory die and a logic die, a package on package (POP) technology is used, in which the logic die is disposed on a front side redistribution layer (FRDL) structure, the memory die is disposed on a back side redistribution layer (BRDL) structure, and the FRDL structure and the BRDL structure are connected by conductive posts.

Even in these mobile devices, large-scale parallel operations are performed, or high-performance computing is required, and for this, it is necessary to apply a PIM semiconductor to the POP structure.

### SUMMARY

PIM semiconductors may be applied to package-on-package (POP) structures.

A PIM die may be mounted on an upper package in the package-on-package (POP) structure. In a conventional package-on-package (POP) structure, the memory die of the upper package is electrically connected to a logic die in a lower package through conductive posts, but the PIM die of the upper package according to the present disclosure may be electrically connected directly to the logic die of the lower package without passing through the conductive posts.

A semiconductor package according to an embodiment includes a first redistribution layer structure, a logic die on the first redistribution layer structure, a plurality of conductive posts on the first redistribution layer structure and next to the logic die, a second redistribution layer structure on the logic die, and a processing in memory (PIM) die on the second redistribution layer structure.

A semiconductor package according to an embodiment includes a first redistribution layer structure, a logic die on the first redistribution layer structure, a plurality of conductive posts on the first redistribution layer structure and next to the logic die, a second redistribution layer structure on the logic die, and a memory package on the second redistribution layer structure, wherein the memory package includes a memory and a processing in memory (PIM).

A semiconductor package according to an embodiment includes a first redistribution layer structure, a logic die on the first redistribution layer structure, a plurality of conductive posts on the first redistribution layer structure and next to the logic die, a first molding material covering the logic die and the plurality of conductive posts on the first redistribution layer structure, a second redistribution layer structure on the first molding material, a processing in memory (PIM) die on the second redistribution layer structure, a memory die on the second redistribution layer structure and next to the PIM die, and a second molding material covering the PIM die and the memory die on the second redistribution layer structure.

A semiconductor package may be provided in which a PIM die is disposed in an upper package, a logic die is disposed in a lower package, and a transmission path for signals transmitted between the PIM die and the logic die is efficiently implemented. As a result, in the semiconductor, it is possible to solve the problem of data movement stagnation between the memory die and the logic die, improve the operation speed of the logic die, and reduce the power consumption of the semiconductor package.

### BRIEF DESCRIPTION OF THE DRAWINGS

FIG. 1 is a cross-sectional view illustrating a semiconductor package according to an embodiment.

FIG. 2 is a cross-sectional view illustrating a semiconductor package according to an embodiment.

FIG. 3 is a cross-sectional view illustrating a semiconductor package according to an embodiment.

FIG. 4 is a cross-sectional view illustrating a semiconductor package according to an embodiment.

FIG. 5 is a cross-sectional view illustrating a semiconductor package according to an embodiment.

FIG. 6 is a cross-sectional view illustrating a semiconductor package according to an embodiment.

FIGS. 7 to 16 are cross-sectional views illustrating a method for manufacturing the semiconductor package according to an embodiment of FIG. 1.

### DETAILED DESCRIPTION

Hereinafter, the present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Size and thickness of each constituent element in the drawings are arbitrarily illustrated for better understanding and ease of description, the following embodiments are not limited thereto.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact. In addition, unless explicitly described to the contrary, the word “comprise”, and variations such as “comprises” or “comprising”, will be understood to imply the inclusion of stated elements but not the exclusion of any other elements.

Spatially relative terms, such as “beneath,” “below,” “lower,” “above,” “upper” and the like, may be used herein for ease of description to describe positional relationships, such as illustrated in the figures, e.g. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed. Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package 100 and a method for manufacturing the semiconductor package 100 according to embodiments will be described with reference to the drawings.

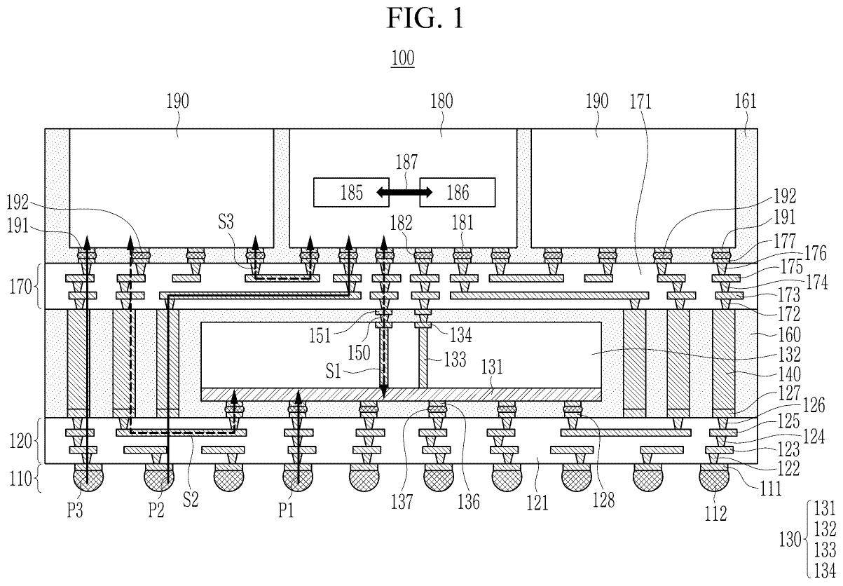

FIG. 1 is a cross-sectional view illustrating the semiconductor package 100 according to an embodiment.

Referring to FIG. 1, the semiconductor package 100 may include an external connection structure 110, a front side redistribution layer structure (a first redistribution layer structure) 120, a logic die 130, conductive posts 140, vias 150, a first molding material 160, a back side redistribution layer structure (a second redistribution layer structure) 170, a PIM die 180, a memory die 190, and a second molding material 161. In an embodiment, the semiconductor package 100 may include a package on package (POP). In an embodiment, the semiconductor package 100 may be manufactured based on a fan out wafer level package (FOWLP) or a fan out panel level package (FOPLP) technology.

The external connection structure 110 is disposed on the lower surface of the front side redistribution layer structure 120. The external connection structure 110 may include conductive pads 111 and external connection members 112. Each of the conductive pads 111 electrically connects each of first redistribution vias 122 of the front redistribution layer structure 120 to each of the external connection members 112. The external connection members 112 electrically connect the semiconductor package 100 to an external device (not shown).

The front side redistribution layer structure 120 is disposed on the external connection structure 110. The front side redistribution layer structure 120 may include a first dielectric 121, first redistribution vias 122, first redistribution lines 123, second redistribution vias 124, second redistribution lines 125 and third redistribution vias 126 within the first dielectric 121, and first pads 127 and second pads 128 on the first dielectric 121. In other embodiments, the front side redistribution layer structure 120 including fewer or more redistribution lines, redistribution vias, and pads are included within the scope of the present disclosure.

The first dielectric 121 protects and insulates the first redistribution vias 122, the first redistribution lines 123, the second redistribution vias 124, the second redistribution lines 125, and third redistribution vias 126. The logic die 130, the first conductive posts 140, and the first molding material 160 are disposed on the upper surface of the first dielectric 121. The external connection structure 110 is disposed on the lower surface of the first dielectric 121.

Each of the first redistribution vias 122 is disposed between each of the first redistribution lines 123 and each of the conductive pads 111. Each of the first redistribution vias 122 extends in the vertical direction and electrically connects each of the first redistribution lines 123 to each of the conductive pads 111. Each of the first redistribution lines 123 extends in the horizontal direction and is disposed between each of the first redistribution vias 122 and each of the second redistribution vias 124. Each of the first redistribution lines 123 electrically connects each of the first redistribution vias 122 and each of the second redistribution vias 124. Each of the second redistribution vias 124 extends in the vertical direction and is disposed between each of the first redistribution lines 123 and each of the second redistribution lines 125. Each of the second redistribution vias 124 electrically connects each of the second redistribution lines 125 to each of the first redistribution lines 123. Each of the second redistribution lines 125 extends in the horizontal direction and is disposed between each of the second redistribution vias 124 and each of the third redistribution vias 126. Each of the second redistribution lines 125 electrically connects each of the second redistribution vias 124 and each of the third redistribution vias 126. Each of the third redistribution vias 126 extends in the vertical direction and is disposed between each of the first pads 127 and each of the second redistribution lines 125, or between each of the second pads 128 and each of the second redistribution lines 125. Each of the third redistribution vias 126 electrically connects each of the first pads 127 to each of the second redistribution lines 125, or each of the second pads 128 to each of the second redistribution lines 125. Each of the first pads 127 is disposed between each of the third redistribution vias 126 and each of the conductive posts 140 which extend in the vertical direction. Each of the first pads 127 electrically connects each of the conductive posts 140 to each of the third redistribution vias 126. Each of the second pads 128 is disposed between each of the third redistribution vias 126 and each of first connection members 137. Each of the second pads 128 electrically connects each of the first connection members 137 to each of the third redistribution vias 126.

The logic die 130 is disposed on the front side redistribution layer structure 120. The logic die 130 is disposed side by side with the conductive posts 140. The logic die 130 may include an active region 131, a logic die base (a first die base) 132, through silicon vias (TSV) 133, and upper connection pads 134. In an embodiment, the logic die 130 may include a system on chip (SoC). In an embodiment, the logic die 130 may include an application processor (AP). In an embodiment, the logic die 130 may include at least one of a central processing unit (CPU), a graphics processing unit (GPU), a signal processor, a network processor, and a codec.

The active region 131 is formed on a front side of a logic die base 132. The active region 131 is formed on the logic die base 132 in a front-end-of-line (FEOL) process. The active region 131 is disposed to face the front side redistribution layer structure 120. The active region 131 includes integrated circuit structures. In an embodiment, integrated circuit structures may include at least one of active devices and passive devices. In an embodiment, integrated circuit structures may include a gate structure, a source region, and a drain region. In an embodiment, integrated circuit structures may include at least one of a transistor, diode, capacitor, inductor, and resistor.

The logic die base 132 includes the front side and a back side. The front side faces the front side redistribution layer structure 120. The back side faces a back side redistribution layer structure 170. The logic die base 132 may be a die formed from a wafer. In an embodiment, the logic die base 132 may include silicon or other semiconductor material. In an embodiment, the logic die base 132 may include a well doped with an impurity or a structure doped with an impurity. The logic die base 132 may have various device isolation structures, such as a shallow trench isolation (STI) structure. In an embodiment, the logic die base 132 may include bulk silicon, silicon-on-insulator (SOI), silicon substrate, silicon germanium, siliconGermanium-on-insulator (SGOI), silicon carbide, indium antimonide, lead tellurium compound, indium arsenide, indium phosphide, gallium arsenide, or gallium antimonide.

Through silicon vias 133 extend in the vertical direction from the front side to the back side of the logic die base 132. The through silicon vias 133 are formed in a back-end-of-line (BEOL) process. The through silicon vias 133 extend through the active region 131 and the logic die base 132. Each of the through silicon vias 133 electrically connects each of the integrated circuit structures of the active region 131 to each of the upper connection pads 134. The footprint of through silicon vias 133 is included within the footprint of the PIM die 180. For example, as illustrated in the cross-sectional view of FIG. 1, the PIM die 180 completely overlaps the through silicon vias 133 in the vertical direction. In an embodiment, the through silicon vias 133 may include at least one of tungsten, aluminum, copper, and alloys thereof.

Each of the upper connection pads 134 is disposed between each of the vias 150 and each of the through silicon vias 133. Each of the upper connection pads 134 electrically connects each of the vias 150 to each of the through silicon vias 133. In an embodiment, the upper connection pads 134 may include at least one of copper, aluminum, silver, tin, gold, nickel, lead, titanium, and alloys thereof.

Each of first connection pads 136 is disposed between each of the wirings of the logic die 130 and each of the first connection members 137. Each of the first connection pads 136 electrically connects each of the wirings of the logic die 130 to each of the first connection members 137. In an embodiment, the first connection pads 136 may include at least one of copper, aluminum, silver, tin, gold, nickel, lead, titanium, and alloys thereof.

Each of the first connection members 137 is disposed between each of the first connection pads 136 and each of the second pads 128. Each of the first connection members 137 electrically connects each of the first connection pads 136 to each of the second pads 128. In an embodiment, the first connection members 137 may include micro bumps or solder balls. In an embodiment, the first connection members 137 may include at least one of tin, silver, lead, nickel, copper, and alloys thereof.

The conductive posts 140 are disposed on the upper surface of the front side redistribution layer structure 120. The conductive posts 140 are disposed around the logic die 130. The conductive posts 140 are disposed next to the logic die 130. Each of the conductive posts 140 is disposed between each of the first pads 127 of the front side redistribution layer structure 120 and each of fourth redistribution vias 172 of the back side redistribution layer structure 170. Each of the conductive posts 140 electrically connects each of the fourth redistribution layer vias 172 of back side redistribution layer structure 170 to each of the first pads 127 of the front side redistribution layer structure 120. The conductive posts 140 are disposed through the first molding material 160. The sides of the conductive posts 140 are surrounded by the first molding material 160.

The vias 150 are disposed on the back side of logic die base 132. Each of the vias 150 extends in the vertical direction and is disposed between each of the upper connection pads 134 and each of the second connection pads 151. Each of the vias 150 electrically connects each of the second connection pads 151 to each of the upper connection pads 134. In an embodiment, the vias 150 may include at least one of copper, aluminum, silver, tin, gold, nickel, lead, titanium, and alloys thereof.

Each of the second connection pads 151 is disposed between each of the vias 150 and each of the fourth redistribution vias 172 of the back side redistribution layer structure 170. Each of the second connection pads 151 electrically connects each of the fourth redistribution vias 172 of the back side redistribution layer structure 170 to each of the vias 150. In one embodiment, the second connection pads 151 may include at least one of copper, aluminum, silver, tin, gold, nickel, lead, titanium, and alloys thereof.

The first molding material 160 covers the logic die 130, the conductive posts 140, and the vias 150 on the front side redistribution layer structure 120. The first molding material 160 protects the logic die 130, the conductive posts 140, and the vias 150 from the external environment, and thus the semiconductor package 100 may secure electrical or mechanical stability.

The back side redistribution layer structure 170 is disposed on the logic die 130, the first molding material 160, and the conductive post 140. The back side redistribution layer structure 170 includes a second dielectric 171, fourth redistribution vias 172, third redistribution lines 173, fifth redistribution vias 174, fourth redistribution lines 175 and sixth redistribution vias 176 in the second dielectric 171, and third pads 177 on the second dielectric 171. In other embodiments, the back side redistribution layer structure 170 including fewer or more redistribution lines, redistribution vias, and pads are included within the scope of the present disclosure.

The second dielectric 171 protects and insulates the fourth redistribution vias 172, the third redistribution lines 173, the fifth redistribution vias 174, the fourth redistribution lines 175, and sixth redistribution vias 176. The PIM die 180, the memory die 190, and the second molding material 161 are disposed on the upper surface of the second dielectric 171. The conductive posts 140, the second connection pads 151, and first molding material 160 are disposed on the lower surface of the second dielectric 171.

Each of the fourth redistribution vias 172 extends in the vertical direction and is disposed between each of the third redistribution lines 173 and each of the conductive posts 140, or between each of the third redistribution lines 173 and each of the second connection pads 151. Each of the fourth redistribution vias 172 electrically connects each of the third redistribution lines 173 to each of the conductive posts 140, or each of the third redistribution lines 173 to each of the second connection pads 151. Each of the third redistribution lines 173 is disposed between each of the fourth redistribution vias 172 and each of the fifth redistribution vias 174. Each of the third redistribution lines 173 extends in the horizontal direction and electrically connects each of the fourth redistribution vias 172 and each of the fifth redistribution vias. Each of the fifth redistribution vias 174 extends in the vertical direction and is disposed between each of the third redistribution lines 173 and each of the fourth redistribution lines 175. Each of the fifth redistribution vias 174 electrically connects each of the fourth redistribution lines 175 to each of the third redistribution lines 173. Each of the fourth redistribution lines 175 is disposed between each of the fifth redistribution vias 174 and each of the sixth redistribution vias 176. Each of the fourth redistribution lines 175 extends in the horizontal direction and electrically connects each of the fifth redistribution vias 174 and each of the sixth redistribution vias 176, or the sixth redistribution vias 176. Each of the sixth redistribution vias 176 extends in the vertical direction and is disposed between each of the fourth redistribution lines 175 and each of the third pads 177. Each of the sixth redistribution vias 176 electrically connects each of the third pads 177 to each of the fourth redistribution lines 175. Each of the third pads 177 is disposed between each of the sixth redistribution vias 176 and each of the second connection members 182, or between each of the sixth redistribution vias 176 and each of third connection members 192. Each of the third pads 177 electrically connects each of the second connection members 182 to each of the sixth redistribution vias 176, or each of the third connection members 192 to each of the sixth redistribution vias 176.

The PIM die 180 is disposed on the back side redistribution layer structure 170. The PIM die 180 is disposed next to the memory die 190. Since the PIM die 180 includes an operation device in the memory or in the memory die, operations may be performed on the memory itself or on the memory die itself without moving data to the logic die 130. By using the PIM die 180, bottlenecks caused by memory bandwidth may be avoided when large-scale parallel operations are performed. In an embodiment, the PIM die 180 may be one to which an in-memory computing (IMC) model or a near-memory computing (NMC) model is applied.

The PIM die 180 may include memory banks 185 and one or more processing units 186 (e.g., a programmable computing unit (PCU), logic unit, etc.), or may include memory banks 185 including one or more processing units 186. The PIM die 180 may include an internal memory bus 187. The internal memory bus 187 is a data transmission path that allows data to be transmitted and received between the memory banks 185 included in the PIM die 180 and the one or more processing units 186.

The memory bank 185 is partitioned areas within memory that operate sequentially to allow data to continuously flow to the processor. The memory bank 185 includes a plurality of columns and rows of memory units. The memory bank 185 processes memory requests. In an embodiment, a memory request may include at least one of read, write, copy, and erase.

The processing unit 186 performs a PIM operation based on data read from the memory bank 185. The processing unit 186 may include register files. In an embodiment, the register files may include at least one of a command register file (CRF), a global register file (GRF), and a scalar register file (SRF) used in PIM operations. In an embodiment, the PIM operation may include at least one of an arithmetic operation, a logic operation, and a shift operation. In an embodiment, arithmetic operations may include addition, multiplication, and accumulation. In an embodiment, the logical operation may include AND, OR, and XOR. In an embodiment, the PIM operation may include a Matrix Vector Multiplication operation. The processing unit 186 performs a PIM operation and passes the operation result to the logic die 130 or writes the operation result to the memory bank 185.

Third connection pads 181 are disposed on the lower surface of the PIM die 180. Each of third connection pads 181 is disposed between each of the wirings of the PIM die 180 and each of the second connection members 182. Each of the third connection pads 181 electrically connects each of the wirings of the PIM die 180 to each of the second connection members 182. In an embodiment, the third connection pads 181 may include at least one of copper, aluminum, silver, tin, gold, nickel, lead, titanium, and alloys thereof.

Each of the second connection members 182 is disposed between each of the third connection pads 181 and each of the third pads 177. Each of the second connection members 182 electrically connects each of the third connection pads 181 to each of the third pads 177. In an embodiment, the second connection members 182 may include micro bumps or solder balls. In an embodiment, the second connection members 182 may include at least one of tin, silver, lead, nickel, copper, and alloys thereof.

The memory die 190 is disposed on the back side redistribution layer structure 170. The memory die 190 is disposed next to the PIM die 180. There may be a plurality of memory dies 190, and the plurality of memory dies 190 may be arranged around the PIM die 180. In an embodiment, the memory die 190 may include a single chip, such as DRAM, or multiple chips, such as high bandwidth memory (HBM). The memory die 190 may include memory banks.

Fourth connection pads 191 are disposed on the lower surface of the memory die 190. Each of the fourth connection pads 191 is disposed between each of the wirings of the memory die 190 and each of the third connection members 192. Each of the fourth connection pads 191 electrically connects each of the wirings of the memory die 190 to each of the third connection members 192. In an embodiment, the fourth connection pads 191 may include at least one of copper, aluminum, silver, tin, gold, nickel, lead, titanium, and alloys thereof.

Each of the third connection members 192 is disposed between each of the fourth connection pads 191 and each of the third pads 177. Each of the third connection members 192 electrically connects each of the fourth connection pads 191 to each of the third pads 177. In an embodiment, the third connection members 192 may include micro bumps or solder balls. In an embodiment, the third connection members 192 may include at least one of tin, silver, lead, nickel, copper, and alloys thereof.

The second molding material 161 covers the PIM die 180 and the memory die 190 on the back side redistribution layer structure 170. The second molding material 161 protects the PIM die 180 and the memory die 190 from the external environment, thereby ensuring electrical or mechanical stability of the semiconductor package 100.

In the semiconductor package 100 having a package-on-package (PoP) structure, in order to transfer the result of the PIM operation performed in the processing unit 186 to the logic die 130 or write the result to the memory bank 185, the signal transmission path between the PIM die 180 and the logic die 130 must be implemented as the shortest path.

Each of first signals S1 transmitted between the PIM die 180 and the logic die 130 may be routed through each of the through silicon vias 133, each of the vias 150, and the back side redistribution layer structure 170. For example, the transmission path of the first signal S1 may include a path passing through the active region 131, the through silicon via 133, the upper connection pad 134, the via 150, the second connection pads 151, the fourth redistribution via 172, the third redistribution line 173, the fifth redistribution via 174, the fourth redistribution line 175, the sixth redistribution via 176, the third pad 177, the second connection member 182, and the third connection pad 181.

Each of second signals S2 transmitted between the memory die 190 and the logic die 130 may be routed through the front side redistribution layer structure 120, each of the conductive posts 140, and the back side redistribution layer structure 170. For example, the transmission path of the second signal S2 may include a path passing through the active region 131, the first connection pad 136, the first connection member 137, the second pad 128, the third redistribution via 126, the second redistribution line 125, the third redistribution via 126, the first pad 127, the conductive post 140, the fourth redistribution via 172, the third redistribution line 173, the fifth redistribution via 174, the fourth redistribution line 175, the sixth redistribution via 176, the third pad 177, the third connection member 192, and the fourth connection pad 191.

Each of third signals S3 transmitted between the PIM die 180 and the memory die 190 may be routed through the back side redistribution layer structure 170. For example, the transmission path of the third signal S3 may include a path passing through the third connection pad 181, the second connection member 182, the third pad 177, the sixth redistribution via 176, and the fourth redistribution line 175, the sixth redistribution via 176, the third pad 177, the third connection member 192, and the fourth connection pad 191.

Each of first powers P1 transmitted to the logic die 130 may be routed through the front side redistribution layer structure 120. For example, the transmission path of the first power P1 may include a path passing through the external connection member 112, the conductive pad 111, the first redistribution via 122, the first redistribution line 123, the second redistribution via 124, the second redistribution line 125, the third redistribution via 126, the second pad 128, the first connection member 137, the first connection pad 136, and the active region 131.

Each of second powers P2 transmitted to the PIM die 180 may be routed through the front side redistribution layer structure 120, each of the conductive posts 140, and the back side redistribution layer structure 170. For example, the transmission path of the second power P2 may include a path passing through the external connection member 112, the conductive pad 111, the first redistribution via 122, the first redistribution line 123, the second redistribution via 124, the second redistribution line 125, the third redistribution via 126, the first pad 127, the conductive post 140, the fourth redistribution via 172, third redistribution line 173, the fifth redistribution via 174, the fourth redistribution line 175, the sixth redistribution via 176, the third pad 177, the second connection member 182, and the third connection pad 181.

Each of third powers P3 transmitted to the memory die 190 may be routed through the front side redistribution layer structure 120, each of the conductive posts 140, and the back side redistribution layer structure 170. For example, the transmission path of the third power P3 may include a path passing through the external connection member 112, the conductive pad 111, the first redistribution via 122, the first redistribution line 123, the second redistribution via 124, the second redistribution line 125, the third redistribution via 126, the first pad 127, the conductive post 140, the fourth redistribution via 172, the third redistribution line 173, the fifth redistribution via 174, the fourth redistribution line 175, the sixth redistribution via 176, the third pad 177, the third connection member 192, and fourth connection pad 191.

According to the present disclosure, the PIM die 180 may disposed in a package-on-package (POP) structure, and a signal transmission path between the logic die 130 and the PIM die 180 may be efficiently designed. Accordingly, in the semiconductor package 100 having a package-on-package (POP) structure where concurrent processing of memory requests is required, latency is critical, or large-scale parallel operations are performed, it is possible to solve the problem of data movement stagnation, improve the speed of the logic die 130, and reduce the power consumption of the semiconductor package 100.

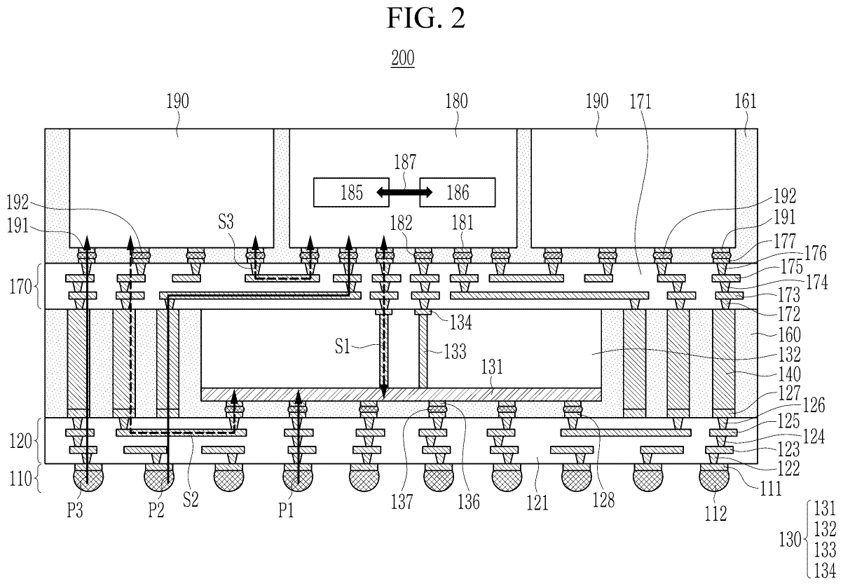

FIG. 2 is a cross-sectional view illustrating a semiconductor package 200 according to an embodiment.

Referring to FIG. 2, the semiconductor package 200 may include a logic die 130 in contact with the back side redistribution layer structure 170. As illustrated in FIG. 2, the first molding material 160 is not disposed between the logic die 130 and the back side redistribution layer structure 170 (e.g., the first molding material does not cover the back side of the logic die base 132). Accordingly, the via 150 and the second connection pads 151 as disclosed with respect to the semiconductor package 100 may be omitted from the semiconductor package 200. Each of the upper connection pads 134 of the logic die 130 respectively contacts a fourth redistribution via 172. Each of the upper connection pads 134 of the logic die 130 is disposed between each of the fourth redistribution vias 172 and each of the through silicon vias 133. Each of the upper connection pads 134 electrically connects each of the fourth redistribution vias 172 to each of the through silicon vias 133. The first molding material 160 covers the logic die 130 and the conductive posts 140 on the front side redistribution layer structure 120. The back side redistribution layer structure 170 is disposed on the first molding material 160, the conductive post 140, and the logic die 130. The logic die 130, the conductive post 140, and the first molding material 160 are disposed on the lower surface of the back side redistribution layer structure 170. For example, the logic die 130, the conductive post 140, and the first molding material 160 contact the lower surface of the back side redistribution layer structure 170.

Each of the first signals S1 transmitted between the PIM die 180 and the logic die 130 may be routed through each of the through silicon vias 133 and the back side redistribution layer structure 170. For example, the transmission path of the first signal S1 may include a path passing through the active region 131, the through silicon via 133, the upper connection pad 134, the fourth redistribution via 172, the third redistribution line 173, the fifth redistribution via 174, the fourth redistribution line 175, the sixth redistribution via 176, the third pad 177, the second connection member 182, and the third connection pad 181.

According to the present disclosure, the transmission path of the first signal S1 between the PIM die 180 and the logic die 130 is shortened, thereby improving signal integrity (SI) and reducing power consumption of the semiconductor package 100.

For contents other than those described with respect to the embodiment of FIG. 2, the contents described with respect to the semiconductor package 100 of FIG. 1 are equally applied.

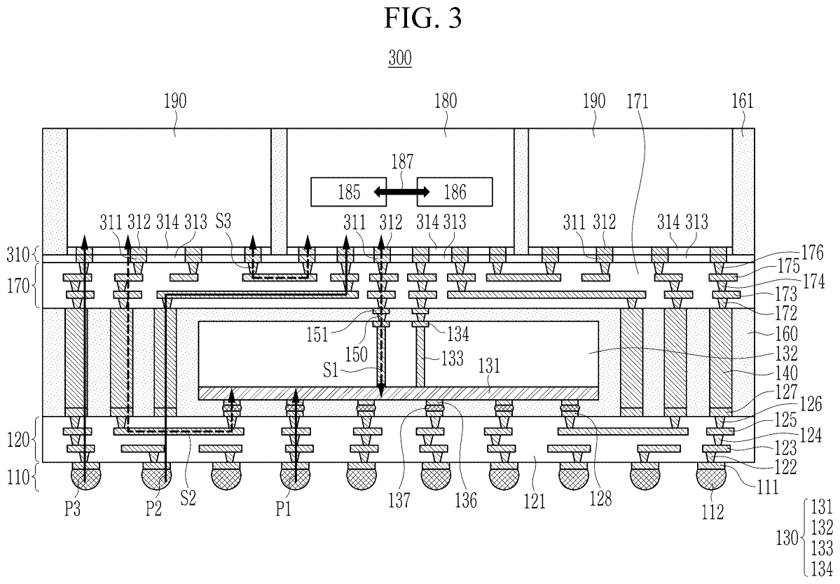

FIG. 3 is a cross-sectional view illustrating a semiconductor package 300 according to an embodiment.

Referring to FIG. 3, the semiconductor package 300 may include an interconnection structure 310. The interconnection structure 310 is disposed between the back side redistribution layer structure 170 and the PIM die 180, and between the back side redistribution layer structure 170 and the memory die 190. The interconnection structure 310 couples the back side redistribution layer structure 170 and the PIM die 180, and the back side redistribution layer structure 170 and the memory die 190 to each other by hybrid bonding.

Hybrid bonding is to bond two devices by fusing the same materials of the two devices using the bonding properties of the same material. Here, hybrid means that two different types of bonding are made, for example, bonding two devices with a first type of metal-metal bonding and a second type of non-metal-non-metal bonding. According to hybrid bonding, I/O with a fine pitch may be formed.

The interconnection structure 310 includes first bonding pads 311, second bonding pads 312, a first silicon insulating layer 313, and a second silicon insulating layer 314. The first bonding pads 311 are disposed on the upper surface of the back side redistribution layer structure 170. The first bonding pads 311 penetrate the first silicon insulating layer 313. The second bonding pads 312 are disposed on the lower surface of the PIM die 180, on the lower surface of the memory die 190, and on the first bonding pads 311. The second bonding pads 312 penetrate the second silicon insulating layer 314. The first silicon insulating layer 313 is disposed on the upper surface of the back side redistribution layer structure 170. The first silicon insulating layer 313 surrounds and insulates the first bonding pads 311. The second silicon insulating layer 314 is disposed on the lower surface of the PIM die 180, on the lower surface of the memory die 190, and on the first silicon insulating layer 313. The second silicon insulating layer 314 surrounds and insulates the second bonding pads 312.

The first bonding pad 311 is directly bonded to the second bonding pad 312 by metal-metal hybrid bonding. Metal bonding is formed at an interface between the first bonding pad 311 and the second bonding pad 312 by metal-metal hybrid bonding. In an embodiment, the first bonding pad 311 and the second bonding pad 312 may each include copper. In another embodiment, the first bonding pad 311 and the second bonding pad 312 may each be made of a metallic material capable of applying hybrid bonding.

Since the first bonding pad 311 and the second bonding pad 312 are made of the same material, the interface between the first bonding pad 311 and the second bonding pad 312 may disappear after hybrid bonding. The back side redistribution layer structure 170 and the PIM die 180, and the back side redistribution layer structure 170 and the memory die 190 are electrically connected to each other through the first bonding pad 311 and the second bonding pad 312.

The first silicon insulating layer 313 is directly bonded to the second silicon insulating layer 314 by non-metal-non-metal hybrid bonding. A covalent bonding is formed at the interface between the first silicon insulating layer 313 and the second silicon insulating layer 314 by non-metal-non-metal hybrid bonding. In an embodiment, the first silicon insulating layer 313 and the second silicon insulating layer 314 may each include silicon oxide or TEOS forming oxide. In an embodiment, the first silicon insulating layer 313 and the second silicon insulating layer 314 may each include SiO₂. In an embodiment, the first silicon insulating layer 313 and the second silicon insulating layer 314 may each be silicon nitride, silicon oxynitride, or other suitable dielectric. In an embodiment, the first silicon insulating layer 313 and the second silicon insulating layer 314 may each include SiN or SiCN.

Since the first silicon insulating layer 313 and the second silicon insulating layer 314 are made of the same material, an interface between the first silicon insulating layer 313 and the second silicon insulating layer 314 may disappear after hybrid bonding.

The back side redistribution layer structure 170 may include the second dielectric 171, and the fourth redistribution vias 172, the third redistribution lines 173, the fifth redistribution vias 174, the fourth redistribution lines 175, and the sixth redistribution vias 176 in the second dielectric 171.

Each of first signals S1 transmitted between the PIM die 180 and the logic die 130 may be routed through each of the through silicon vias 133, each of the vias 150, the back side redistribution layer structure 170, and the interconnection structure 310. For example, the transmission path of the first signal S1 may include a path passing through the active region 131, the through silicon via 133, the upper connection pad 134, the via 150, the second connection pads 151, the fourth redistribution via 172, the third redistribution line 173, the fifth redistribution via 174, the fourth redistribution line 175, the sixth redistribution via 176, the first bonding pad 311, and the second bonding pad 312.

Each of the second signals S2 transmitted between the memory die 190 and the logic die 130 may be routed through the front side redistribution layer structure 120, each of the conductive posts 140, the back side redistribution layer structure 170, and the interconnection structure 310. For example, the transmission path of the second signal S2 may include a path passing through the active region 131, the first connection pad 136, the first connection member 137, the second pad 128, the third redistribution via 126, the second redistribution line 125, the third redistribution via 126, the first pad 127, the conductive post 140, the fourth redistribution via 172, the third redistribution line 173, the fifth redistribution via 174, the fourth redistribution line 175, the sixth redistribution via 176, the first bonding pad 311, and the second bonding pad 312.

Each of the third signals S3 transmitted between the PIM die 180 and the memory die 190 may be routed through the back side redistribution layer structure 170 and the interconnection structure 310. For example, the transmission path of the third signal S3 may include a path passing through the second bonding pad 312, the first bonding pad 311, the sixth redistribution via 176, the fourth redistribution line 175, and the sixth redistribution via 176, the first bonding pad 311, and the second bonding pad 312.

Each of first powers P1 transmitted to the logic die 130 may be routed through the front side redistribution layer structure 120. For example, the transmission path of the first power P1 may include a path passing through the external connection member 112, the conductive pad 111, the first redistribution via 122, the first redistribution line 123, the second redistribution via 124, the second redistribution line 125, the third redistribution via 126, the second pad 128, the first connection member 137, the first connection pad 136, and the active region 131.

Each of second powers P2 transmitted to the PIM die 180 may be routed through the front side redistribution layer structure 120, each of the conductive posts 140, the back side redistribution layer structure 170, and the interconnection structure 310. For example, the transmission path of the second signal S2 may include a path passing through the external connection member 112, the conductive pad 111, the first redistribution via 122, the first redistribution line 123, the second redistribution via 124, the second redistribution line 125, the third redistribution via 126, the first pad 127, the conductive post 140, the fourth redistribution via 172, the third redistribution line 173, the fifth redistribution via 174, the fourth redistribution line 175, the sixth redistribution via 176, the first bonding pad 311, and the second bonding pad 312.

Each of third powers P3 transmitted to the memory die 190 may be routed through the front side redistribution layer structure 120, each of the conductive posts 140, the back side redistribution layer structure 170, and interconnection structure 310. For example, the transmission path of the third power P3 may include a path passing through the external connection member 112, the conductive pad 111, the first redistribution via 122, the first redistribution line 123, the second redistribution via 124, the second redistribution line 125, the third redistribution via 126, the first pad 127, the conductive post 140, the fourth redistribution via 172, the third redistribution line 173, the fifth redistribution via 174, the fourth redistribution line 175, the sixth redistribution via 176, the first bonding pad 311, and the second bonding pad 312.

For contents other than those described with respect to the embodiment of FIG. 3, the contents described with respect to the semiconductor package 100 of FIG. 1 are equally applied.

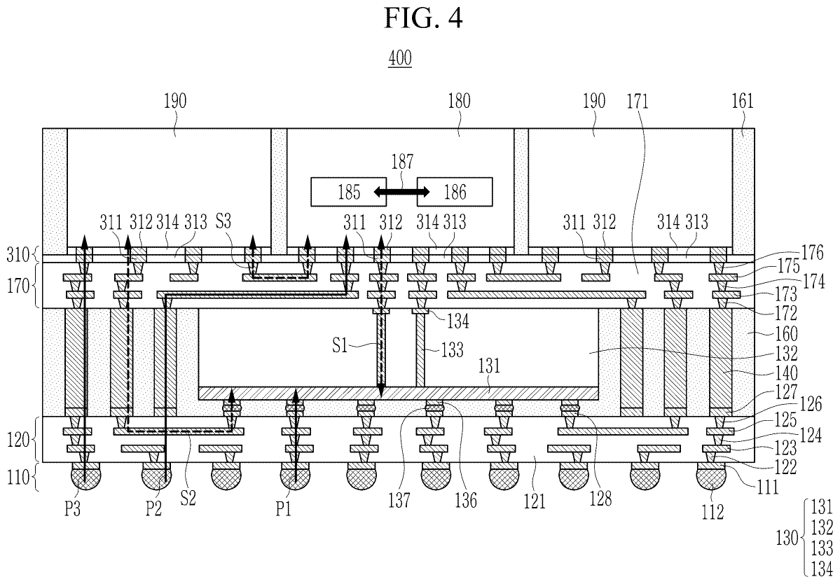

FIG. 4 is a cross-sectional view illustrating a semiconductor package 400 according to an embodiment.

Referring to FIG. 4, the semiconductor package 400 may include a logic die 130 in contact with the back side redistribution layer structure 170. Additionally, the semiconductor package 400 may include the interconnection structure 310. For the logic die 130 in contact with the back side redistribution layer structure 170, the same description as for the semiconductor package 200 of FIG. 2 will be applied. For the interconnection structure 310, the same description as for the semiconductor package 300 of FIG. 3 will be applied. For other contents, the same contents described for the semiconductor package 100 of FIG. 1 will be applied.

Each of the first signals S1 transmitted between the PIM die 180 and the logic die 130 may be routed through each of the through silicon vias 133, the back side redistribution layer structure 170, and the interconnection structure 310. For example, the transmission path of the first signal S1 may include a path passing through the active region 131, the through silicon via 133, the upper connection pad 134, the fourth redistribution via 172, the third redistribution line 173, the fifth redistribution via 174, the fourth redistribution line 175, the sixth redistribution via 176, the first bonding pad 311, and the second bonding pad 312.

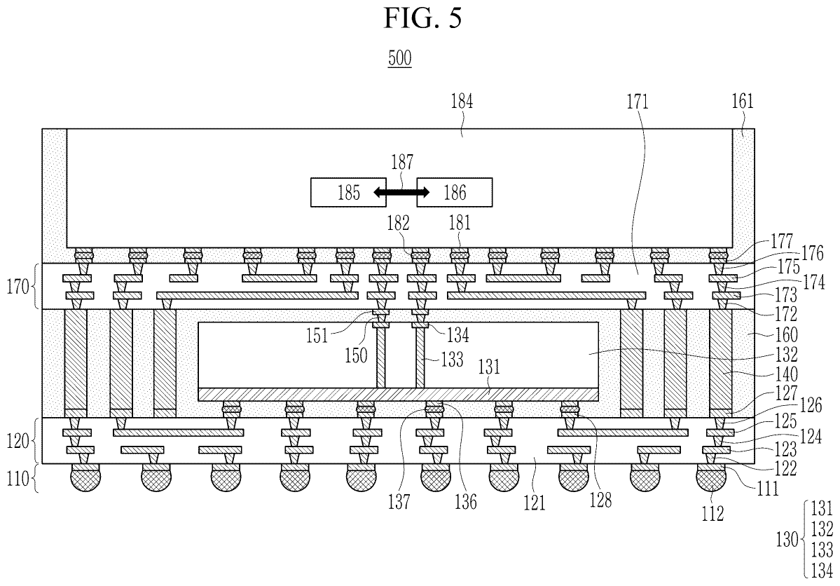

FIG. 5 is a cross-sectional view illustrating a semiconductor package 500 according to an embodiment.

Referring to FIG. 5, the semiconductor package 500 may include a memory package 184. The memory package 184 is disposed on the back side redistribution layer structure 170. The memory package 184 may include a memory including memory banks 185, internal memory bus 187, and one or more processing units 186 communicatively connected to the memory via the internal memory bus to form a PIM architecture within the memory package 184. The memory package 184 may include the internal memory bus 187, which is a data transmission path that allows data to be transmitted and received between the memory banks 185 and the one or more processing units 186. In an embodiment, the memory package 184 may be one to which an in-memory computing (IMC) model or a near-memory computing (NMC) model is applied.

The third connection pads 181 are disposed on the lower surface of the memory package 184. Each of the third connection pads 181 is disposed between each of the wirings of the memory package 184 and each of the second connection members 182. Each of the third connection pads 181 electrically connects each of the wirings of the memory package 184 to each of the second connection members 182.

Each of the second connection members 182 is disposed between each of the third connection pads 181 and each of the third pads 177. Each of the second connection members 182 electrically connects each of the third connection pads 181 to each of the third pads 177.

The second molding material 161 covers the memory package 184 on the back side redistribution layer structure 170.

For contents other than those described with respect to the embodiment of FIG. 5, the contents described with respect to the semiconductor package 100 of FIG. 1 are equally applied.

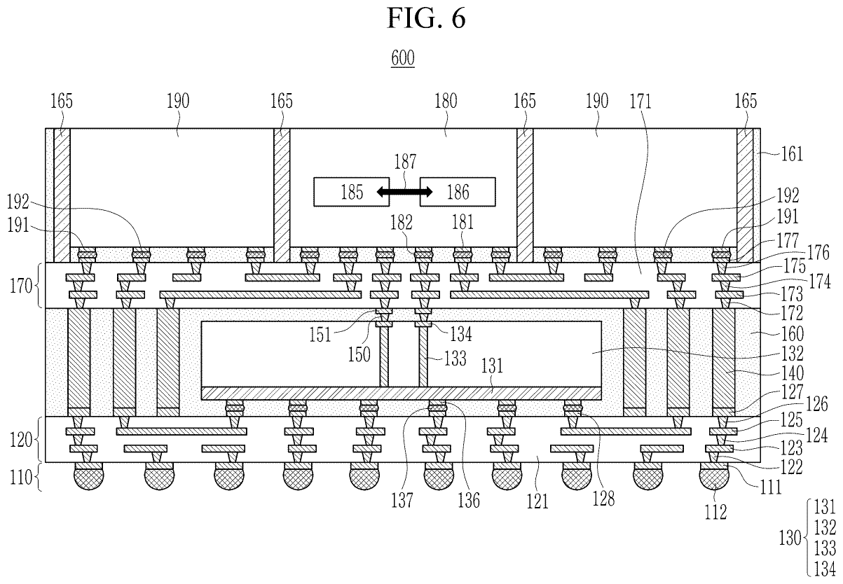

FIG. 6 is a cross-sectional view illustrating a semiconductor package 600 according to an embodiment.

Referring to FIG. 6, the semiconductor package 600 may include a heat dissipation structure 165. The heat dissipation structure 165 is disposed on the back side redistribution layer structure 170. The heat dissipation structure 165 may be disposed between the PIM die 180 and the memory die 190, or may surround the PIM die 180 and the memory die 190, or may be locally disposed at a position where heat of the PIM die 180 is generated or at a position where heat of the memory die 190 is generated. In an embodiment, the heat dissipation structure 165 may include a conductive material. In an embodiment, the heat dissipation structure 165 may include copper, aluminum, gold, silver, iron, or stainless steel (SUS). In an embodiment, the heat dissipation structure 165 may include a silicon material having higher thermal conductivity compared to the second molding material 161. In an embodiment, the heat dissipation structure 165 may include a thermal interface material (TIM). The thermal interface material (TIM) is a material that is inserted to improve thermal coupling with a heat dissipating device (for example, the PIM die 180 or the memory die 190). The thermal interface material (TIM) serves to reduce thermal contact resistance by filling the air gap at the contact surface between devices that dissipate heat. In an embodiment, the thermal interface material (TIM) may include thermal paste, thermal pad, phase change material (PCM), or metallic material. In an embodiment, the thermal interface material (TIM) may include grease.

In this way, by disposing the heat dissipation structure 165 on the back side redistribution layer structure 170, it is possible to dissipate the heat generated within the PIM die 180 and the memory die 190 to the outside through the heat dissipation structure 165. Accordingly, the thermal characteristics of the semiconductor package 600 may be improved.

For contents other than those described with respect to the embodiment of FIG. 6, the contents described with respect to the semiconductor package 100 of FIG. 1 are equally applied.

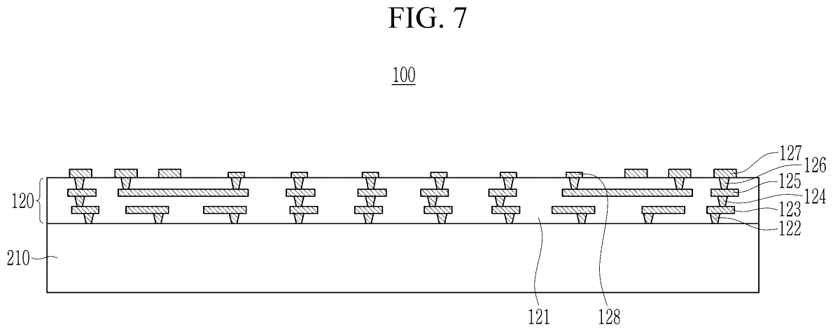

FIGS. 7 to 16 are cross-sectional views illustrating a method for manufacturing the semiconductor package 100 according to an embodiment of FIG. 1.

FIG. 7 is a cross-sectional view illustrating a step of forming the front side redistribution layer structure 120 on a carrier 210.

Referring to FIG. 7, the front side redistribution layer structure 120 is formed on the carrier 210. First, the carrier 210 is provided. In an embodiment, the carrier 210 may include glass or a silicon-based material such as silicon oxide, an organic material, or another material such as aluminum oxide, any combination of these materials.

Next, the first dielectric 121 is deposited on the carrier 210. In an embodiment, the first dielectric 121 may include photo-imageable dielectrics (PID) used in a redistribution layer process. For example, the photo-imageable dielectrics (PID) may include a polyimide-based photo-imageable polymer, a novolak-based photo-imageable polymer, polybenzoxazole, a silicone-based polymer, an acrylate-based polymer, or an epoxy-based polymer. In an embodiment, the first dielectric 121 may be formed by performing a spin coating process.

After forming the first dielectric 121, the first dielectric 121 is selectively etched to form via holes, and the via holes are filled with a conductive material to form the first redistribution vias 122. After forming the first redistribution vias 122, the first dielectric 121 is further formed on the first redistribution vias 122 and the first dielectric 121, and the further formed first dielectric 121 is selectively etched to form openings, and the openings are filled with a conductive material to form the first redistribution lines 123. After forming the first redistribution lines 123, the first dielectric 121 is further formed on the first redistribution lines 123 and the first dielectric 121, and the further formed first dielectric 121 is selectively etched to form via holes, and the via holes are filled with a conductive material to form the second redistribution vias 124. After forming the second redistribution vias 124, the first dielectric 121 is further formed on the second redistribution vias 124 and the first dielectric 121, and the further formed first dielectric 121 is selectively etched to form openings, and the openings are filled with a conductive material to form the second redistribution lines 125. After forming the second redistribution lines 125, the first dielectric 121 is further formed on the second redistribution lines 125 and the first dielectric 121, and the further formed first dielectric 121 is selectively etched to form via holes, and the via holes are filled with a conductive material to form the third redistribution vias 126. After forming the third redistribution vias 126, photoresist is further deposited on the third redistribution vias 126 and the first dielectric 121, the photoresist is selectively exposed and developed to form a photoresist pattern including via holes, and via holes are filled with a conductive material to form the first pads 127 and the second pads 128.

In an embodiment, the first redistribution vias 122, the first redistribution lines 123, the second redistribution vias 124, the second redistribution lines 125, the third redistribution vias 126, the first pads 127, and the second pads 128 may each include at least one of copper, aluminum, tungsten, nickel, gold, tin, titanium, and alloys thereof. In an embodiment, the first redistribution vias 122, the first redistribution lines 123, the second redistribution vias 124, the second redistribution lines 125, the third redistribution vias 126, the first pads 127, and the second pads 128 may each be formed by performing a sputtering process. In another embodiment, the first redistribution vias 122, the first redistribution lines 123, the second redistribution vias 124, the second redistribution lines 125, the third redistribution vias 126, the first pads 127, and the second pads 128 may be formed by forming a seed metal layer and then performing an electrolytic plating process.

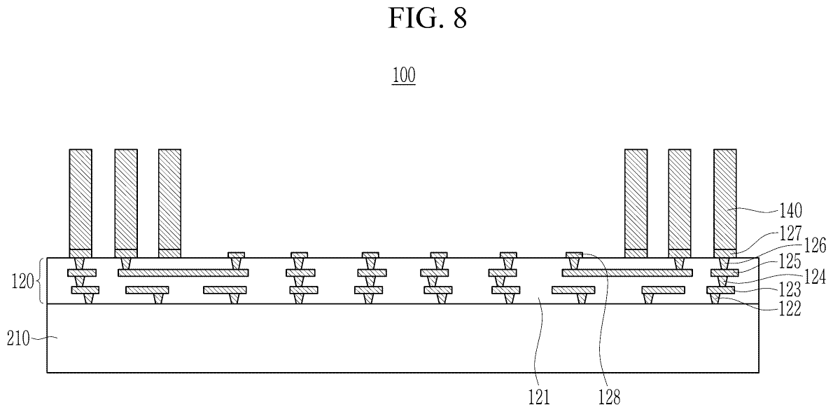

FIG. 8 is a cross-sectional view illustrating a step of forming the conductive posts 140 on the front side redistribution layer structure 120.

Referring to FIG. 8, the conductive posts 140 are formed on the front side redistribution layer structure 120. In an embodiment, the conductive posts 140 may be formed by performing a sputtering process. In another embodiment, the conductive posts 140 may be formed by forming a seed metal layer and then performing an electrolytic plating process. In an embodiment, the conductive posts 140 may include at least one of copper, aluminum, tungsten, nickel, gold, silver, chromium, antimony, tin, titanium, and alloys thereof.

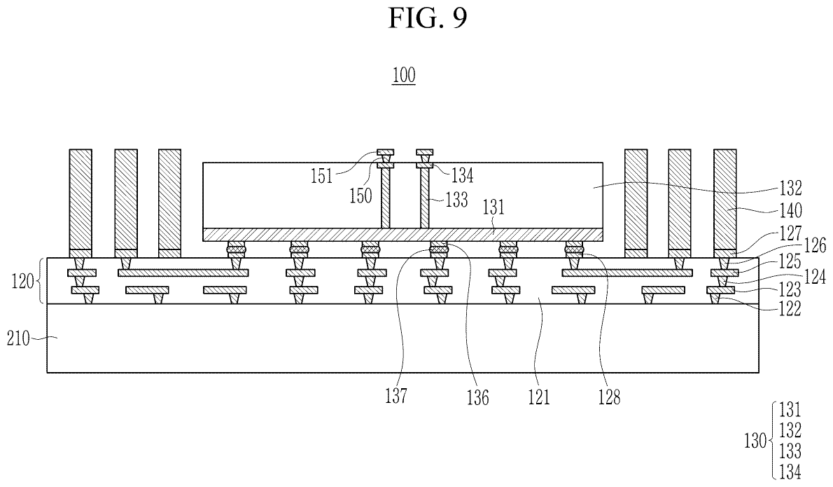

FIG. 9 is a cross-sectional view illustrating a step of mounting the logic die 130 on the front side redistribution layer structure 120.

Referring to FIG. 9, the logic die 130 is mounted on the front side redistribution layer structure 120. In an embodiment, the logic die 130 may be bonded to the front side redistribution layer structure 120 by performing a flip chip bonding process. The logic die 130 is bonded to the first pads 127 of the front side redistribution layer structure 120 by the first connection members 137, thereby electrically connecting the logic die 130 and the front side redistribution layer structure 120.

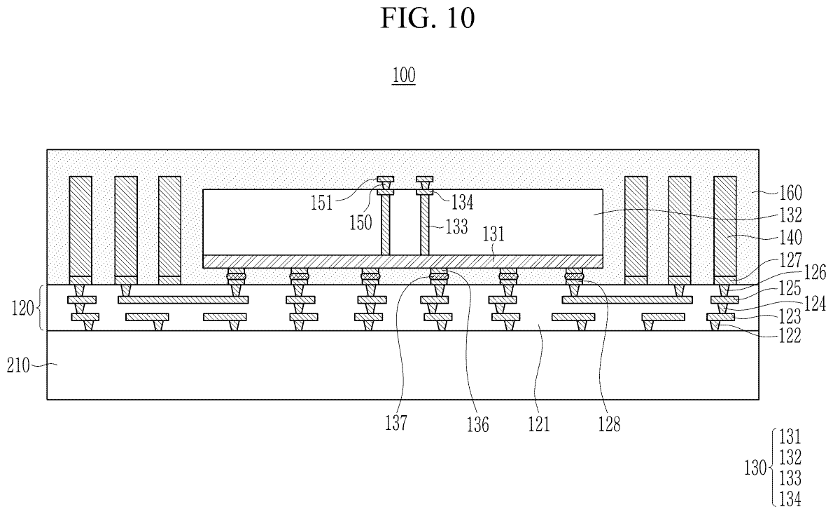

FIG. 10 is a cross-sectional view illustrating a step of molding the logic die 130 and the conductive posts 140 on the front side redistribution layer structure 120.

Referring to FIG. 10, the logic die 130 and the conductive posts 140 are molded (i.e., covered) on the front side redistribution layer structure 120 by the first molding material 160. For example, the process of molding with the first molding material 160 may include a compression molding or transfer molding process. In an embodiment, the first molding material 160 may include epoxy molding compound (EMC).

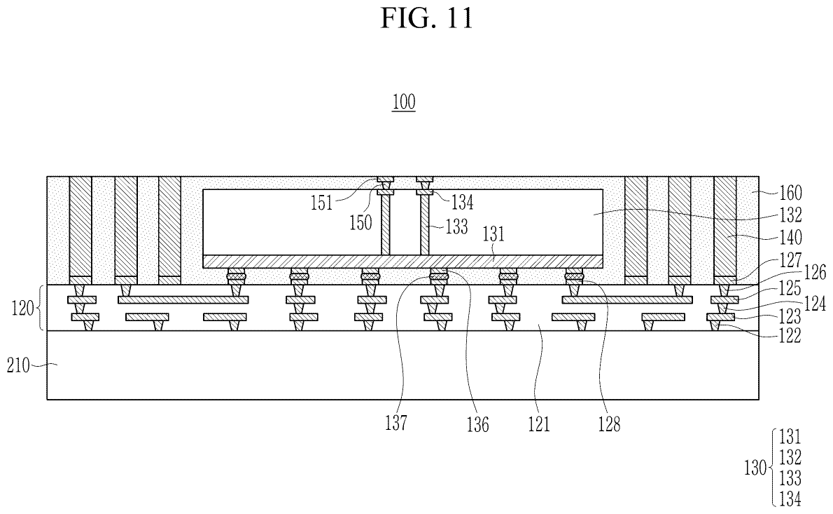

FIG. 11 is a cross-sectional view illustrating a step of performing a chemical mechanical planarization (CMP) process on the first molding material 160.

Referring to FIG. 11, the chemical mechanical planarization (CMP) process is performed to level the upper surface of the first molding material 160, thereby planarizing the upper surface of the first molding material 160. After performing the chemical mechanical planarization (CMP) process, the upper surfaces of the second connection pads 151 and the conductive posts 140 are exposed.

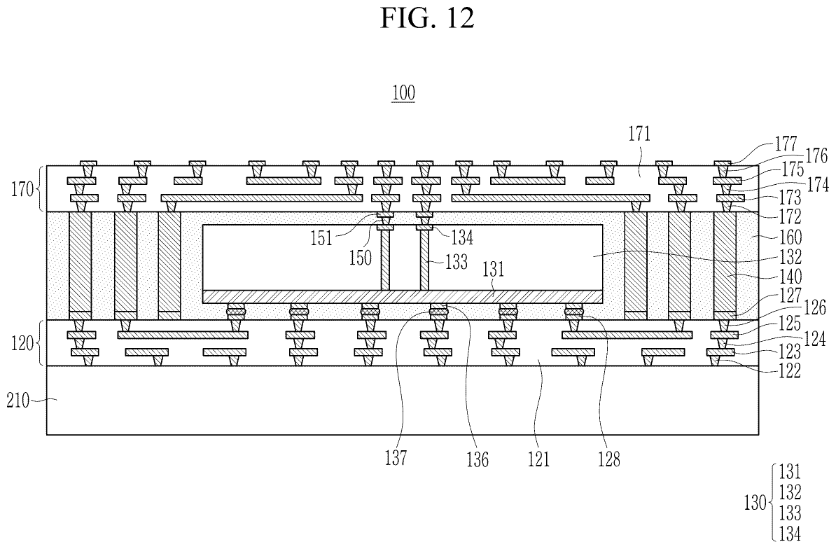

FIG. 12 is a cross-sectional view illustrating a step of forming the back side redistribution layer structure 170 on the conductive posts 140, the second connection pads 151, and the first molding material 160.

Referring to FIG. 12, the second dielectric 171 is deposited on the conductive posts 140, the second connection pads 151, and the first molding material 160. In an embodiment, the second dielectric 171 may include a photo-imageable dielectric (PID) used in a redistribution layer process. For example, the photo-imageable dielectrics (PID) may include a polyimide-based photo-imageable polymer, a novolak-based photo-imageable polymer, polybenzoxazole, a silicone-based polymer, an acrylate-based polymer, or an epoxy-based polymer. In an embodiment, the second dielectric 171 may be formed by performing a spin coating process.

After forming the second dielectric 171, the second dielectric 171 is selectively etched to form via holes, and the via holes are filled with a conductive material to form the fourth redistribution vias 172. After forming the fourth redistribution vias 172, the second dielectric 171 is further formed on the fourth redistribution vias 172 and the second dielectric 171, and the further formed second dielectric 171 is selectively etched to form openings, and the openings are filled with a conductive material to form the third redistribution lines 173. After forming the third redistribution lines 173, the second dielectric 171 is further formed on the third redistribution lines 173 and the second dielectric 171, and the further formed second dielectric 171 is selectively etched to form via holes, and the via holes are filled with a conductive material to form the fifth redistribution vias 174. After forming the fifth redistribution vias 174, the second dielectric 171 is further formed on the fifth redistribution vias 174 and the second dielectric 171, and the further formed second dielectric 171 is selectively etched to form openings, and the openings are filled with a conductive material to form the fourth redistribution lines 175. After forming the fourth redistribution lines 175, the second dielectric 171 is further formed on the fourth redistribution lines 175 and the second dielectric 171, and the further formed second dielectric 171 is selectively etched to form via holes, and the via holes are filled with a conductive material to form the sixth redistribution vias 176. After forming the sixth redistribution vias 176, photoresist is further deposited on the sixth redistribution vias 176 and the second dielectric 171, the photoresist is selectively exposed and developed to form a photoresist pattern including via holes, and via holes are filled with a conductive material to form the third pads 177.

In an embodiment, the fourth redistribution vias 172, the third redistribution lines 173, the fifth redistribution vias 174, the fourth redistribution lines 175, the sixth redistribution vias 176, and the third pads 177 may each include at least one of copper, aluminum, tungsten, nickel, gold, tin, titanium, and alloys thereof. In an embodiment, the fourth redistribution vias 172, the third redistribution lines 173, the fifth redistribution vias 174, the fourth redistribution lines 175, the sixth redistribution vias 176, and the third pads 177 may each be formed by performing a sputtering process. In another embodiment, the fourth redistribution vias 172, the third redistribution lines 173, the fifth redistribution vias 174, the fourth redistribution lines 175, the sixth redistribution vias 176, and the third pads 177 may be formed by forming a seed metal layer and then performing an electrolytic plating process.

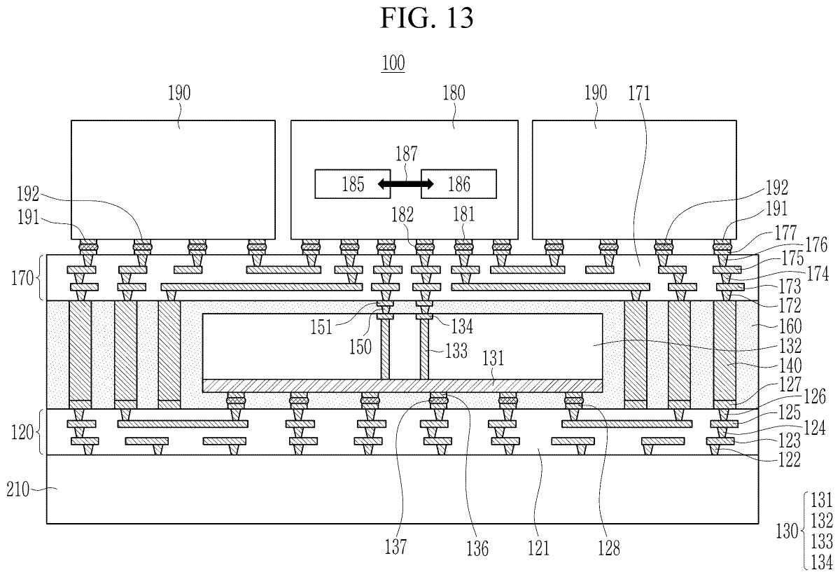

FIG. 13 is a cross-sectional view illustrating a step of mounting the PIM die 180 and the memory die 190 on the back side redistribution layer structure 170.

Referring to FIG. 13, the PIM die 180 and the memory die 190 are mounted on the back side redistribution layer structure 170. In an embodiment, the PIM die 180 and the memory die 190 may each be bonded to the back side redistribution layer structure 170 by performing a flip chip bonding process. The PIM die 180 is bonded to the third pads 177 of the back side redistribution layer structure 170 by the second connection members 182, the memory die 190 is bonded to the third pads 177 of the back side redistribution layer structure 170 by the third connection members 192. Accordingly, the PIM die 180 and the back side redistribution layer structure 170, and the memory die 190 and the back side redistribution layer structure 170 are electrically connected.

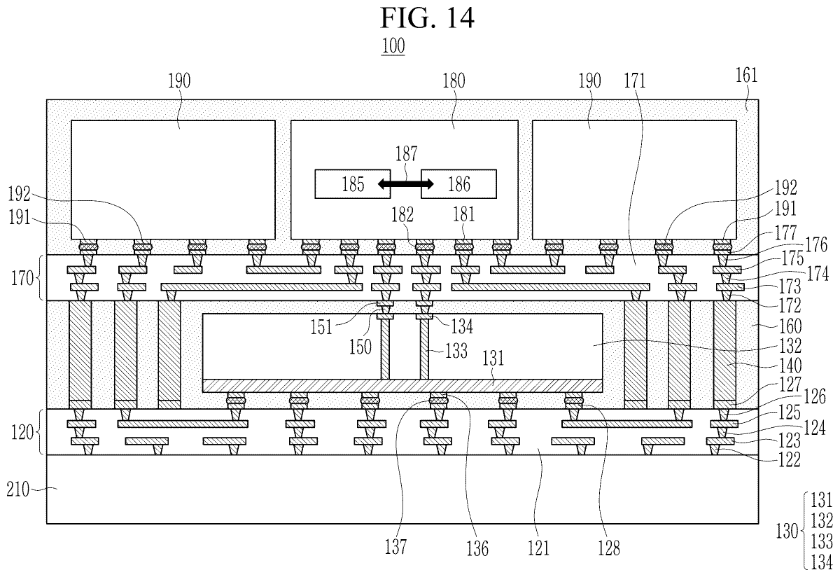

FIG. 14 is a cross-sectional view illustrating a step of molding the PIM die 180 and the memory die 190 on the back side redistribution layer structure 170.

Referring to FIG. 14, the PIM die 180 and the memory die 190 are molded on the back side redistribution layer structure 170 by the second molding material 161. For example, the process of molding with the second molding material 161 may include a compression molding or transfer molding process. In an embodiment, the second molding material 161 may include epoxy molding compound (EMC).

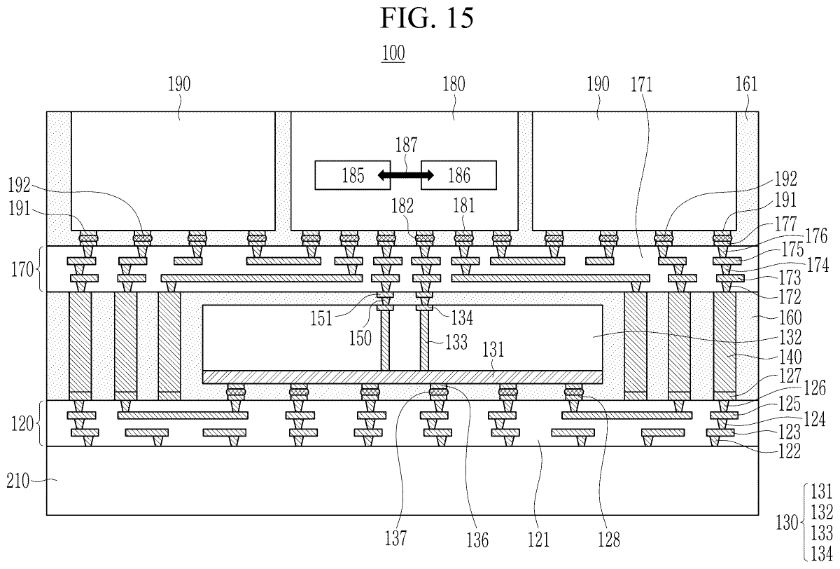

FIG. 15 is a cross-sectional view illustrating a step of performing a chemical mechanical planarization (CMP) process on the second molding material 161.

Referring to FIG. 15, the chemical mechanical planarization (CMP) process is performed to level the upper surface of the second molding material 161, thereby planarizing the upper surface of the second molding material 161. After performing the chemical mechanical planarization (CMP) process, the upper surfaces of the PIM die 180 and the memory die 190 are exposed.

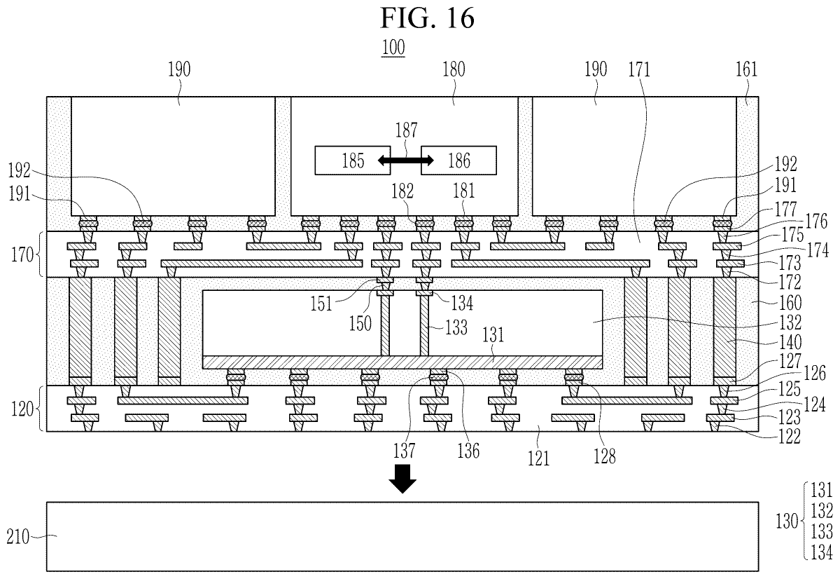

FIG. 16 is a cross-sectional view illustrating a step of removing the carrier 210 from the front side redistribution layer structure 120.

Referring to FIG. 16, the carrier 210 is removed from the lower surface of the front side redistribution layer structure 120. Thereafter, as shown in FIG. 1, the external connection structure 110 is formed on the lower surface of the front side redistribution layer structure 120. The conductive pads 111 are formed under the first redistribution vias 122 of the front side redistribution layer structure 120. In an embodiment, the conductive pad 111 may include at least one of copper, nickel, zinc, gold, silver, platinum, palladium, chromium, titanium, and alloys thereof. In an embodiment, the conductive pad 111 may be formed through a sputtering process, or by forming a seed metal layer and then performing an electrolytic plating process. Thereafter, the external connection member 112 is formed under the conductive pads 111. In an embodiment, the external connection member 112 may include at least one of tin, silver, lead, nickel, copper, and alloys thereof.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package, comprising:
a first redistribution layer structure;
a logic die on the first redistribution layer structure;
a plurality of conductive posts on the first redistribution layer structure and next to the logic die;
a second redistribution layer structure on the logic die; and
a processing in memory (PIM) die on the second redistribution layer structure.

2. The semiconductor package of claim 1, wherein
the logic die comprises a plurality of through silicon vias.

3. The semiconductor package of claim 2, wherein
signals transmitted between the logic die and the PIM die are routed through each of the plurality of through silicon vias and the second redistribution layer structure.

4. The semiconductor package of claim 1, wherein
the logic die is in contact with the second redistribution layer structure.

5. The semiconductor package of claim 1, further comprising
a plurality of vias between the logic die and the second redistribution layer structure.

6. The semiconductor package of claim 5, wherein
the logic die comprises a plurality of through silicon vias,
and signals transmitted between the logic die and the PIM die are routed through each of the plurality of through silicon vias, each of the plurality of vias, and the second redistribution layer structure.

7. The semiconductor package of claim 1, wherein
the PIM comprises
a memory bank; and
a processing unit performing an operation based on data read from the memory bank.

8. The semiconductor package of claim 7, wherein
a result of the operation is transmitted to the logic die or written to the memory bank.

9. The semiconductor package of claim 2, wherein
footprints of the plurality of through silicon vias are included in the footprint of the PIM die.

10. The semiconductor package of claim 1, wherein
the logic die comprises
a logic die base including a front side and a back side; and
an active region on the front side,
the front side faces the first redistribution layer structure,
and the back side faces the second redistribution layer structure.

11. The semiconductor package of claim 1, wherein
power supplied to the PIM die is routed through some of the plurality of conductive posts.

12. The semiconductor package of claim 1, further comprising
a plurality of micro bumps between the second redistribution layer structure and the PIM die.

13. The semiconductor package of claim 1, further comprising
an interconnection structure between the second redistribution layer structure and the PIM die,
wherein the interconnection structure comprises
a plurality of first bonding pads;
a first silicon insulating layer surrounding the plurality of first bonding pads;
a plurality of second bonding pads on the plurality of first bonding pads, wherein each of the plurality of second bonding pads are directly bonded to each of the plurality of first bonding pads; and
a second silicon insulating layer on the first silicon insulating layer, wherein the second silicon insulating layer surrounds the plurality of second bonding pads and is directly bonded to the first silicon insulating layer.

14. A semiconductor package, comprising:
a first redistribution layer structure;
a logic die on the first redistribution layer structure;
a plurality of conductive posts on the first redistribution layer structure and next to the logic die;
a second redistribution layer structure on the logic die; and
a memory package on the second redistribution layer structure, wherein the memory package includes a memory, a bus, and a processing unit communicatively connected to the memory via the bus to form a processing in memory (PIM) architecture within the memory package.

15. The semiconductor package of claim 14, wherein
the logic die comprises an application processor (AP).

16. A semiconductor package, comprising:
a first redistribution layer structure;
a logic die on the first redistribution layer structure;
a plurality of conductive posts on the first redistribution layer structure and next to the logic die;
a first molding material covering the logic die and the plurality of conductive posts on the first redistribution layer structure;
a second redistribution layer structure on the first molding material;
a processing in memory (PIM) die on the second redistribution layer structure;
a memory die on the second redistribution layer structure and next to the PIM die; and
a second molding material covering the PIM die and the memory die on the second redistribution layer structure.

17. The semiconductor package of claim 16, wherein
power supplied to the memory die is routed through some of the plurality of conductive posts.

18. The semiconductor package of claim 16, wherein
signals transmitted between the logic die and the memory die are routed through the first redistribution layer structure, each of the plurality of conductive posts, and the second redistribution layer structure.

19. The semiconductor package of claim 16, wherein
signals transmitted between the PIM die and the memory die are routed through the second redistribution layer structure.

20. The semiconductor package of claim 16, further comprising
a heat dissipation structure between the PIM die and the memory die.
